(19) United States
(12) Patent Application Publication
(10) Pub. No.: US 2025/0172863 A1
(43) Pub. Date: May 29, 2025

(54) REFLECTIVE MASK BLANK AND REFLECTIVE MASK

(71) Applicant: AGC Inc., Tokyo (JP)

(72) Inventor: Takeshi OKATO, Tokyo (JP)

(73) Assignee: AGC Inc., Tokyo (JP)

(21) Appl. No.: 19/026,233

(22) Filed: Jan. 16, 2025

Related U.S. Application Data
(63) Continuation of application No. PCT/JP2023/027271, filed on Jul. 25, 2023.

(30) Foreign Application Priority Data
Aug. 3, 2022 (JP) 2022-124350

(51) Int. Cl. G03F 1/24

(52) U.S. Cl. CPC G03F 1/24

(57) ABSTRACT

A reflective mask blank 10 for EUV lithography in which a multi-layer reflection film 2 that reflects EUV light and an absorption layer 3 that absorbs EUV light are laminated on a substrate 1 in the stated order from the substrate 1 side, wherein the absorption layer 3 has a refractive index of 0.930 or less and an extinction coefficient of 0.025 or more for EUV light having a wavelength of 13.5 nm, and a phase difference between reflected light from a surface of the multi-layer reflection film and reflected light from a surface of the absorption layer with respect to an incident ray of the EUV light having a wavelength of 13.5 nm is 220 to 280°, and a reflective mask in which a mask pattern is formed on the absorption layer 3.

### CROSS-REFERENCE TO RELATED PATENT APPLICATIONS

This application is a U.S. Bypass Continuation of International Patent Application No. PCT/JP2023/027271, filed on Jul. 25, 2023, which is based upon and claims the benefit to Japanese Patent Application No. 2022-124350, filed on Aug. 3, 2022. The contents of these applications are hereby incorporated by reference in their entireties.

### TECHNICAL FIELD

The present invention relates to a reflective mask blank for use in extreme ultraviolet (EUV) lithography in semiconductor manufacturing and the like, and a reflective mask with the reflective mask blank.

### BACKGROUND ART

In a reflective mask for use in EUV lithography, a mask pattern by an absorption layer that absorbs EUV light is provided on a multi-layer reflection film that reflects short-wavelength EUV light having a wavelength of about 13.5 nm. In the reflective mask, an increased thickness of the absorption layer is likely to cause a dimension error of a transfer pattern due to so-called shadowing in which EUV light entering obliquely (typically at an incidence angle of) 6° and a reflected ray of the light are blocked.

For suppressing a dimension error due to the shadowing, efforts are being made so that the thickness of an absorption layer of a mask is as small as possible. In addition, technical development of phase shift masks is underway to improve the resolution of an edge portion of the transfer pattern by an absorption layer formed so as to absorb EUV light and reflect light such that it differs in phase from reflected light from a multi-layer reflection film.

Meanwhile, a transmissive phase shift mask is such that to a transmission portion of a mask pattern, a substance or shape different in refractive index and transmittance from the transmission portion is added to change the phase of the transmitted light of the portion, thereby improving the resolution. In a region where the phase is changed, transmission diffraction rays of light having phase difference interfere with each other, leading to a decrease in light intensity. This improves the contrast of the transfer pattern, so that the focal depth during transfer expands, and transfer accuracy is improved.

In a halftone mask which is a type of transmissive phase shift mask, a thin film semitransparent to exposure light is formed at a portion where the phase of transmitted light is changed. The halftone mask can improve transfer accuracy by reducing the transmittance to approximately several percents (typically about 2.5 to 15.0% relative to the substrate transmitted light), and simultaneously changing the phase to improve the resolution of a pattern edge portion.

The best phase difference is 180° in principle, but it is known that in practice, a resolution improving effect can be obtained when the phase difference is about 175 to 185°.

For the reflective mask for EUV lithography, the principle of improving the resolution by the phase shift effect has been considered the same as that for the transmissive mask except that the “transmittance” is replaced by the “reflectance”. That is, it has been considered desirable that the EUV light reflectance of the absorption layer be 2.5 to 15.0%, and the phase difference between a reflected ray of EUV light from the reflection layer and a reflected ray of EUV light from the absorption layer (hereinafter, also referred to simply as “phase difference”) be 175 to 185°

For this reason, the phase shift mask in a conventional reflective mask is generally designed such that the phase difference is about 180° (corresponding to being substantially reversed) (see, for example, Patent Literature 1).

On the other hand, in the reflective mask, light enters obliquely, unlike the transmissive mask in which light enters perpendicularly, and the optimum phase difference has been recently reported to be 216°(=1.2 π).

### CITATION LIST

### Patent Literature

PTL1: JP 2011-29334 A

### SUMMARY OF INVENTION

### Technical Problem

Thus, the absorption layer of the reflective mask has been designed such that on the basis of a refractive index of a constituent material (which may be represented by n hereinafter) and an extinction coefficient (which may be represented by k hereinafter), the thickness of the absorption layer is set so that the phase difference is 180° or 216°, but the optimum values of the reflectance, the phase difference and the thickness of the absorption layer vary depending on exposure conditions, a shape of the transfer pattern and the like, and are difficult to simply define.

On the other hand, the demand for finer patterns has further increased and patterning processes have become more complicated as semiconductor elements and the like have become finer. Improvements made to absorption layers so that it is possible to adequately meet the above demand have not been sufficient yet. For example, for the dimension of a line-like pattern in the fine processing, typically, a half-pitch (½ of the total length of a line width and a line spacing; hereinafter, abbreviated as HP) of a transfer pattern is used as a representative value, and if HP is 16 nm or less, it is difficult to improve the resolution in EUV lithography even when the above-described phase shift mask is used.

In particular, the patterns of LSI have become complicated with an increase in integration density, and have a structure in which orthogonally crossing line-like patterns are complicatedly tangled, and mask patterns are required to meet such a complicated structure.

A reflective mask for EUV lithography becomes more susceptible to shadowing particularly in a direction where the plane of incidence of exposure light and the line width are parallel to each other as HP decreases. Therefore, for forming a mask pattern excellent in transfer accuracy, it is required to develop a phase shift mask provided in advance with an absorption layer which ensures that an optimum reflectance and phase difference can be obtained.

The present invention has been made in view of these circumstances, and an object of the present invention is to provide a reflective mask for EUV lithography which can form a transfer pattern with high dimension accuracy with respect to fine line-like patterns, and a reflective mask blank that is used for the reflective mask.

### Solution to Problem

The present invention is based on the discovery that a transfer pattern can be formed with high dimension accuracy with respect to fine line-like patterns in EUV lithography when a phase difference derived from an absorption layer is larger than conventional ones.

The present invention provides the following means.

[1] A reflective mask blank for EUV lithography in which a multi-layer reflection film that reflects EUV light and an absorption layer that absorbs EUV light are laminated on a substrate in the stated order from the substrate side, wherein the absorption layer has a refractive index of 0.930 or less and an extinction coefficient of 0.025 or more for EUV light having a wavelength of 13.5 nm, and a phase difference between reflected light from a surface of the multi-layer reflection film and reflected light from a surface of the absorption layer with respect to an incident ray of the EUV light having a wavelength of 13.5 nm is 220 to 280°.
[2] The reflective mask blank according to [1], wherein the phase difference is 225 to 280°.
[3] The reflective mask blank according to [1] or [2], wherein a mask pattern comprising a first line-like pattern and a second line-like pattern, line directions of which orthogonally cross each other, is formed on the absorption layer.
[4] The reflective mask blank according to [3], wherein a half-pitch of a transfer pattern formed by the first line-like pattern and the second line-like pattern is 16 nm or less.
[5] The reflective mask blank according to any one of [1] to [4], wherein the absorption layer comprises one or more metal elements selected from the group consisting of iridium (Ir), rhenium (Re), osmium (Os), ruthenium (Ru), platinum (Pt), palladium (Pd), gold (Au) and silver (Ag).
[6] The reflective mask blank according to any one of [1] to [4], wherein the absorption layer comprises one or more metal elements selected from the group consisting of platinum (Pt), palladium (Pd), gold (Au) and silver (Ag).
[7] The reflective mask blank according to any one of [1] to [6], wherein the absorption layer has an extinction coefficient of 0.025 to 0.040 for EUV light having a wavelength of 13.5 nm.
[8] The reflective mask blank according to any one of [1] to [7], wherein the absorption layer is formed by laminating two or more films.
[9] The reflective mask blank according to any one of [1] to [8], wherein the absorption layer has a total thickness of 60 nm or less.
[10] The reflective mask blank according to any one of [1] to [9], wherein a protective film for protecting the multi-layer reflection film is formed between the multi-layer reflection film and the absorption layer.

[11] A reflective mask for EUV lithography in which a multi-layer reflection film that reflects EUV light and an absorption layer that absorbs EUV light are laminated on a substrate in the stated order from the substrate side, wherein the absorption layer has a refractive index of 0.930 or less and an extinction coefficient of 0.025 or more for EUV light having a wavelength of 13.5 nm, a phase difference between reflected light from a surface of the multi-layer reflection film and reflected light from a surface of the absorption layer with respect to an incident ray of the EUV light having a wavelength of 13.5 nm is 220 to 280°, and a mask pattern is formed on the absorption layer.

[12] The reflective mask according to [11], wherein the phase difference is 225 to 280°.

[13] The reflective mask according to [11] or [12], wherein the mask pattern comprises a first line-like pattern and a second line-like pattern, line directions of which orthogonally cross each other.

[14] The reflective mask according to [13], which satisfies all of the following expressions (1) to (3):

$${N}_{V} \geq 2.8 \qquad ( 1 )$$

$${N}_{H} \geq 2.8 \qquad ( 2 )$$

$$\vert {N}_{V} - {N}_{H} \vert / min \{ {N}_{V} , {N}_{H} \} < 0.06 \qquad ( 3 )$$

wherein N_{V} represents a normalized image log slope of a line-like pattern in which a plane of incidence of exposure light is perpendicular to a line width, and N_{H} represents a normalized image log slope of a line-like pattern in which a plane of incidence of exposure light is parallel to a line width.

[15] The reflective mask according to [13] or [14], wherein a half-pitch of a transfer pattern formed by the first line-like pattern and the second line-like pattern of the reflective mask is 16 nm or less.

[16] The reflective mask according to any one of [11] to [15], wherein the absorption layer comprises one or more metal elements selected from the group consisting of iridium (Ir), rhenium (Re), osmium (Os), ruthenium (Ru), platinum (Pt), palladium (Pd), gold (Au) and silver (Ag).

[17] The reflective mask according to any one of [11] to [15], wherein the absorption layer comprises one or more metal elements selected from the group consisting of platinum (Pt), palladium (Pd), gold (Au) and silver (Ag).

[18] The reflective mask according to any one of [11] to [17], wherein the absorption layer has an extinction coefficient of 0.025 to 0.040 for EUV light having a wavelength of 13.5 nm.

### Advantageous Effects of Invention

According to the present invention, there are provided a reflective mask for EUV lithography which can form a transfer pattern with high dimension accuracy for fine line-like patterns, and a reflective mask blank that is used for the reflective mask.

### BRIEF DESCRIPTION OF DRAWINGS

FIG. 1 is a schematic sectional view schematically showing a reflective mask blank according to an embodiment of the present invention.

FIGS. 2A and 2B show schematic plan views of a transfer pattern of a line-and-space pattern. FIG. 2A shows a first line-like transfer pattern, and FIG. 2B shows a second line-like transfer pattern.

FIG. 3 is a schematic sectional view schematically showing a reflective mask according to an embodiment of the present invention.

FIG. 4 is a schematic diagram for illustrating a light intensity distribution in a transfer pattern.

FIGS. 5A and 5B show simulation calculation results for a transfer pattern in EUV lithography (NA=0.33, HP=20 [nm]). FIG. 5A is a diagram in which the distribution of min {N_{V}, N_{H}} with respect to n and k is represented in the form of contour lines, and FIG. 5B is a diagram in which phase differences calculated from the values of d, n and k here are represented in the form of contour lines.

FIGS. 6A and 6B show simulation calculation results for transfer patterns in EUV lithography (NA=0.55, HP=12 [nm]). FIG. 6A is a diagram in which the distribution of min {N_{V}, N_{H}} with respect to n and k is represented in the form of contour lines, and FIG. 6B is a diagram in which phase differences calculated from the values of d, n and k here are represented in the form of contour lines.

FIG. 7 is a graph showing a relationship between k and |N_{V}−N_{H}|/min {N_{V}, N_{H}} on the basis of simulation calculation results for transfer patterns in EUV lithography (NA=0.33, HP=16 [nm], n=0.90).

### DESCRIPTION OF EMBODIMENTS

First, terms in the present specification will be explained.

The meanings of the terms “on a substrate”, “on a layer” and “on a film” (hereinafter, abbreviated as “on a film or the like”) include not only a state of being in contact with an upper surface of a film or the like, but also an upper side that is not in contact with an upper surface of a film or the like. For example, in the case of “a film B on a film A”, the film A and the film B may be in contact with each other, or another film or the like may be interposed between the film A and the film B. The term “upper” used herein does not necessarily mean a high position in the vertical direction, and indicates a relative positional relationship.

The thickness of a film or the like formed can be measured by a transmission electron microscope or an X-ray reflectance method.

A preferred numerical value range can be set by arbitrarily combining a preferred lower limit value and upper limit value.

### [Reflective Mask Blank]

Hereinafter, an embodiment of the present invention will be described with reference to the drawings.

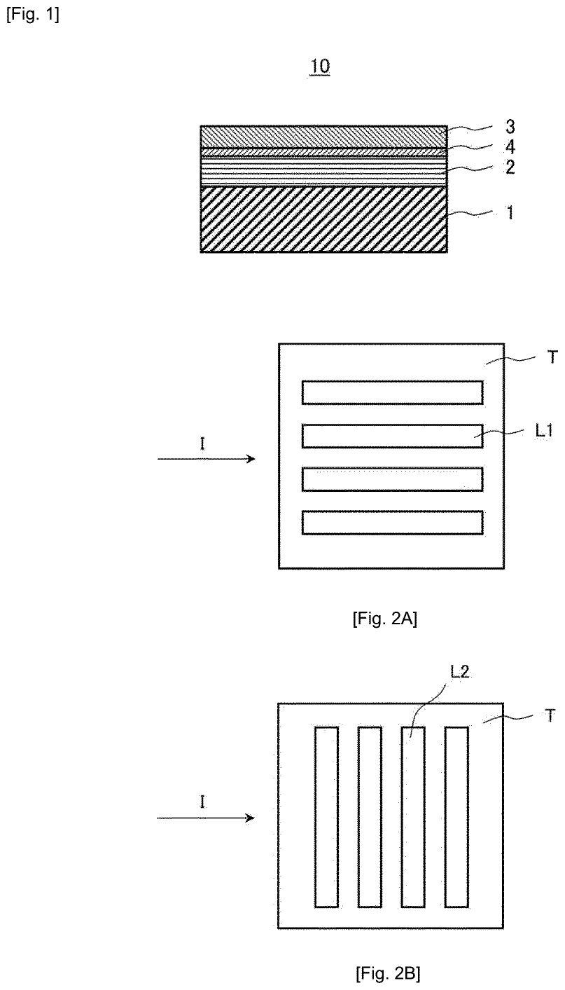

FIG. 1 schematically show a cross-section of a reflective mask blank of the present embodiment. In a reflective mask blank 10 shown in FIG. 1, a multi-layer reflection film 2 that reflects EUV light and an absorption layer 3 that absorbs EUV light are laminated on a substrate 1 in the stated order from the substrate 1 side.

A protective film 4 (also referred to as a cap layer) protecting the multi-layer reflection film 2 from dry etching in formation of a mask pattern may be formed between the multi-layer reflection film 2 and absorption layer 3. Further, an antireflection film (not shown) for facilitating pattern defect inspection after mask processing can be formed on the absorption layer 3.

### (Substrate)

From the viewpoint of preventing distortion of a transfer pattern by heat during EUV exposure, the thermal expansion coefficient of the substrate 1 at 20° C. is preferably low, and is preferably 0±0.05×10⁻⁷/° C., and more preferably 0+0.03×10⁻⁷/° C. Preferably, the substrate 1 is excellent in smoothness, has high flatness, and is excellent in resistance to a cleaning liquid used in production processes for reflective masks (chemical resistance).

Examples of the material for the substrate 1 include SiO₂—TiO₂-based glass, and multicomponent glass ceramics. Crystallized glass in which a solid solution of β-quartz is precipitated, quartz glass, silicon, metal and the like can also be used.

From the viewpoint of enabling pattern transfer to be performed with a high reflectance and high accuracy, the substrate 1 is preferably smooth, and has a surface roughness (RMS) of preferably 0.15 nm or less, and more preferably 0.10 nm or less. From the same viewpoint, the flatness (total indicated reading (TIR)) is preferably 100 nm or less, more preferably 50 nm or less, and further more preferably 30 nm or less.

The substrate 1 preferably has high rigidity from the viewpoint of preventing deformation by stress of a film or the like formed on the substrate 1. Specifically, the Young's modulus is preferably 65 GPa or more.

### (Multi-Layer Reflection Film)

From the viewpoint of increasing the EUV light reflectance, the multi-layer reflection film 2 preferably has a configuration in which a plurality of layers whose main components are elements different in refractive index are laminated in a cyclic manner. In general, the multi-layer reflection film 2 has a structure in which a set of one high refractive index layer and one low refractive index layer is defined as one cycle, and laminated about 40 to 60 cycles.

The high refractive index layer/low refractive index layer is generally a Mo/Si multi-layer reflection film, but is not limited thereto, and examples thereof include Ru/Si multi-layer reflection films, Mo/Be multi-layer reflection films, Mo compound/Si compound multi-layer reflection films, Si/Mo/Ru multi-layer reflection films, Si/Mo/Ru/Mo multi-layer reflection films, Mo/Ru/Si multi-layer reflection films, Si/Ru/Mo multi-layer reflection films, and Si/Ru/Mo/Ru multi-layer reflection films.

The reflectance of the multi-layer reflection film 2 for an incident ray of EUV light having a wavelength of about 13.5 nm at an incidence angle of 6° is preferably 60% or more, and more preferably 65% or more.

The thickness of each of films forming the multi-layer reflection film 2 and the repeated cycle of lamination are appropriately set according to film materials and a desired EUV light reflectance.

The multi-layer reflection film 2 can be formed by, for example, depositing the constituent films to a desired thickness using a known deposition method such as a magnetron sputtering method or an ion beam sputtering method.

For example, when a Mo/Si multi-layer reflection film is formed by an ion beam sputtering method, a Si film is first deposited to a thickness of 4.5 nm with a Si target and a Mo film is subsequently deposited to a thickness of 2.3 nm with a Mo target at an ion accelerating voltage of 300 to 1,500 V and a deposition rate of 0.030 to 0.300 nm/sec using argon (Ar) gas (gas pressure 1.3×10⁻² to 2.7×10⁻² Pa) as a sputtering gas. With this as one cycle, a Mo film/Si film is repeatedly laminated 30 to 60 cycles, whereby a Mo/Si multi-layer reflection film can be formed.

### (Protective Film)

A protective film 4 for protecting the multi-layer reflection film 2 from dry etching in formation of a mask pattern may be formed between the multi-layer reflection film 2 and the absorption layer 3. The protective film 4 also has a role of preventing oxidation of the multi-layer reflection film 2 during EUV exposure, which reduces the EUV light reflectance.

The processability of the absorption layer 3 becomes better as the ratio of rates of etching of the absorption layer 3 and the protective film 4 in the thickness direction with etching gas in the dry etching (etching rate for the absorption layer 3/etching rate for the protective film 4) increases. The etching rate ratio is preferably 10 to 200, and more preferably 30 to 100.

As the etching gas, halogen-based gas, oxygen-based gas or a mixture thereof is typically used. Examples of the halogen-based gas include chlorine-based gas containing one or more selected from the group consisting of Cl₂, SiCl₄, CHCl₃, CCl₄ and BCl₃; and fluorine-based gas containing one or more selected from the group consisting of CF₄, CHF₃, SF₆, BF₃ and XeF₂.

Preferably, the protective film 4 contains one or more elements selected from the group consisting of, for example, Ru, Rh and Si. When containing Rh, the protective film 4 may be composed only of Rh, but also preferably contains one or more elements selected from the group consisting of Ru, Nb, Mo, Ta, Ir, Pd, Zr, Y and Ti. Among these elements, one or more selected from the group consisting of Ru, Ta, Ir, Pd and Y are preferable from the viewpoint of improving resistance to the etching gas, and a sulfuric acid/hydrogen peroxide mixture for use in, for example, cleaning of the reflective mask. From the viewpoint of improving the smoothness of the protective film 4, the protective film 4 may contain one or more elements selected from the group consisting of N, O, C and B.

The protective film 4 may be a single-layer film, or may be a multi-layer film including a plurality of layers. When the protective film 4 is a multi-layer film, it can be formed such that the lower layer of the protective film 4 is in contact with the uppermost surface of the multi-layer reflection film 2, and the upper layer of the protective film 4 is in contact with the lowermost surface of the absorption layer 3. By making the protective film 4 have a multi-layered configuration as described above, a material excellent in predetermined function can be used for each layer to make the whole protective film 4 have multiple functions. For example, the protective film 4 may include a layer free of Rh when having a Rh content of 50 at % or more as a whole. When the protective film 4 is a multi-layer film, the thickness of the protective film 4 means a total thickness of the multi-layer film.

The thickness of the protective film 4 is only required to be within a range which allows the above-described role to be sufficiently performed without interfering with the reflection performance of the multi-layer reflection film 2. The thickness of the protective film 4 is preferably 1.0 to 10.0 nm, and more preferably 2.0 to 3.5 nm.

From the same viewpoint, the protective film 4 has a root mean square (RMS) of preferably 0.3 nm or less, and more preferably 0.1 nm or less, and is preferably smooth.

The protective film 4 can be formed by, for example, deposition to a desired thickness using a known deposition method such as a DC sputtering method, a magnetron sputtering method or an ion beam sputtering method.

Further, a buffer layer (not shown) for protecting the multi-layer reflection film 2 during dry etching and defect repairing may be formed between the protective film 4 and the absorption layer 3. Examples of the constituent material of the buffer layer include, but are not limited to, materials containing SiO₂, Cr, Ta or the like as a main component.

### (Absorption Layer)

The absorption layer 3 is formed such that the refractive index is 0.930 or less and the extinction coefficient is 0.025 or more for EUV light having a wavelength of 13.5 nm, and the phase difference between reflected light from the surface of the multi-layer reflection film 2 and reflected light from the surface of the absorption layer 3 with respect to an incident ray of the EUV light having a wavelength of 13.5 nm is 220 to 280°.

The reflective mask blank of the present embodiment, in which the absorption layer 3 has the above-mentioned characteristics, thus is suitable for a reflective mask for EUV lithography which can transfer fine line-like patterns with high dimension accuracy.

The refractive index of the absorption layer 3 for EUV light having a wavelength of 13.5 nm is 0.930 or less, preferably 0.925 or less, and more preferably 0.920 or less. The refractive index is preferably 0.850 or more.

Since the refractive index is within the above-described range, the phase difference is easily increased, and a phase shift mask capable of transferring fine line-like patterns with high dimension accuracy can be obtained.

The extinction coefficient of the absorption layer 3 for EUV light having a wavelength of 13.5 nm is 0.025 or more, preferably 0.028 to 0.065, and more preferably 0.030 to 0.050.

Since the extinction coefficient is within the above-described range, a phase shift mask capable of transferring fine line-like patterns with high dimension accuracy can be obtained.

For sufficiently exhibiting effects as a phase shift mask, the phase difference between reflected light from the surface of the multi-layer reflection film 2 and reflected light from the surface of the absorption layer 3 with respect to an incident ray of EUV light having a wavelength of 13.5 nm is 220 to 280°, preferably 225 to 280°.

Since the phase difference is within the above-described range, a phase shift mask capable of transferring fine line-like patterns with high dimension accuracy can be obtained.

In the present invention, the term “reflected light from the multi-layer reflection film 2 in the phase shift mask” means that EUV light having a wavelength of 13.5 nm, which has passed through an opening portion of a mask pattern without passing through the absorption layer 3, and directly entered (the protective film 4 and) the multi-layer reflection film 2, is reflected by the multi-layer reflection film 2, and passes through the opening portion of the mask pattern again without passing through the absorption layer 3. The term “reflected light from the surface of the absorption layer 3” means that an incident ray of EUV light having a wavelength of 13.5 nm passes though the absorption layer 3 (and the protective film 4) while being absorbed by the absorption layer 3, is reflected by the multi-layer reflection film 2, and passes through the absorption layer 3 again while being absorbed by the absorption layer 3.

For the absorption layer of the reflective mask for EUV lithography, it is desirable that the thickness be small from the viewpoint of suppressing shadowing as described above, various constituent materials and structures have been under studies, and it has been considered that the best phase difference is 180° or 216°. As the phase difference, a value calculated by optical multi-layer film simulation is used in the present invention, but the phase difference can be roughly represented by the following expression (4).

$$θ = 4 π \{ d / λ - d / ( λ / n ) \} \qquad ( 4 )$$

In expression (4), θ is a phase difference, d is a thickness of the absorption layer 3, λ is a wavelength of incident light, n is a refractive index of the absorption layer 3.

In the present invention, λ=13.5 [nm] and n<1 are met, and thus, an increased refractive index with a decreased thickness leads to a decrease in phase difference of the absorption layer 3.

Examples of the preferred aspect of the fine line-like patterns formed on the absorption layer 3 of the reflective mask blank 10 include mask patterns including a first line-like pattern and a second line-like pattern, line directions of which orthogonally cross each other. The mask pattern formed on the absorption layer 3 of the reflective mask blank 10 is preferably for performing pattern transfer such that a first line-like transfer pattern L1 shown in FIG. 2A is formed on a surface to be transferred T by the first line-like pattern and a second line-like transfer pattern L2 shown in FIG. 2B is formed on the surface to be transferred T by the second line-like pattern, that is, forming a line-and-space pattern (LS pattern).

In both the first line-like transfer pattern L1 and the second line-like transfer pattern L2 on the surface to be transferred T which are shown in FIGS. 2A and 2B, all the line widths and spacings are equal, but there may be a difference between the widths and between the spacings, or there may be a difference between the width and the spacing.

The reflective mask blank 10 is suitable when the transfer pattern formed by the first line-like pattern and the second line-like pattern includes a fine line-like pattern having, for example, a HP of 18 nm or less. More preferably, HP is 16 nm or less.

When HP is within the above-described range, a further excellent effect as a phase shift mask with high dimension accuracy can be obtained.

EUV lithography is reduced projection exposure. The scale of the transfer pattern to the mask pattern is typically 4 times, and thus, for example, when the transfer pattern is an LS pattern which has a HP of 16 nm and in which the line width and the line spacing are equal, the mask pattern is an LS pattern having a HP of 64 nm.

In the case of an LS pattern in which the line width and the line spacing are different, the critical dimension (CD) of the line width at a resolution limit can be considered equivalent to HP.

The material for forming the absorption layer 3 is not limited as long as it can form a phase shift mask as described above. The material preferably contains one or more metal elements selected from the group consisting of Ir, Re, Os, Ru, Pt, Pd, Au and Ag. One metal element alone, or two or more metal elements may be contained. The material may be a single metal element, an alloy, or a compound containing, for example, oxygen (O), nitrogen (N), carbon (C), boron (B) and/or hydrogen (H).

Examples of the material composed of two metal elements include alloys such as PdCr, IrMo, OsRu, RuPt, RuIr, and OsRe. When two or more metal elements are contained, the composition ratio of the metals is not limited as long as the refractive index and the extinction coefficient of the absorption layer 3 satisfy the above-described numerical value ranges.

For example, when the constituent material of the absorption layer 3 is a PdCr alloy, the ratio of the Cr content [at %] to the Pd content [at %] (Cr/Pd) is preferably 0.01 to 20, more preferably 0.1 to 10, and further more preferably 0.2 to 4, from the viewpoint of obtaining desired optical characteristics while suppressing crystallization of the absorption layer 3. The alloy may contain B, N, O, C or the like for controlling crystallization.

For example, when the constituent material of the absorption layer 3 is an IrMo alloy, the ratio of the Mo content [at %] to the Ir content [at %] (Mo/Ir) is preferably 0.01 to 4, more preferably 0.05 to 2, and further more preferably 0.1 to 1, from the viewpoint of obtaining desired optical characteristics while suppressing crystallization of the absorption layer 3. The alloy may contain B, N, O, C or the like for controlling crystallization.

For example, when the constituent material of the absorption layer 3 is an OsRu alloy, the ratio of the Ru content [at %] to the Os content [at %] (Ru/Os) is preferably 0.01 to 4, more preferably 0.05 to 2, and further more preferably 0.1 to 1, from the viewpoint of obtaining desired optical characteristics while suppressing crystallization of the absorption layer 3. The alloy may contain B, N, O, C or the like for controlling crystallization.

For example, when the constituent material of the absorption layer 3 is a RuPt alloy, the ratio of the Pt content [at %] to the Ru content [at %] (Pt/Ru) is preferably 0.01 to 20, more preferably 0.1 to 10, and further more preferably 0.2 to 5, from the viewpoint of obtaining desired optical characteristics while suppressing crystallization of the absorption layer 3. The alloy may contain B, N, O, C or the like for controlling crystallization.

For example, when the constituent material of the absorption layer 3 is a RuIr alloy, the ratio of the Ir content [at %] to the Ru content [at %] (Ir/Ru) is preferably 0.01 to 20, more preferably 0.2 to 10, and further more preferably 0.4 to 4, from the viewpoint of obtaining desired optical characteristics while suppressing crystallization of the absorption layer 3. The alloy may contain B, N, O, C or the like for controlling crystallization.

For example, when the constituent material of the absorption layer 3 is an OsRe alloy, the ratio of the Re content [at %] to the Os content [at %] (Re/Os) is preferably 0.01 to 20, more preferably 0.05 to 10, and further more preferably 0.1 to 5, from the viewpoint of obtaining desired optical characteristics while suppressing crystallization of the absorption layer 3. The alloy may contain B, N, O, C or the like for controlling crystallization.

The absorption layer 3 may have a multi-layered configuration in which two or more films are laminated. It is preferable that the absorption layer 3 has a multi-layered configuration in that predetermined functional layers of different materials can be used as respective layers to design the whole absorption layer 3. Examples of the functional layer include a buffer layer deposited as necessary between the reflection layer and the absorption layer for the purpose of preventing damage given to the reflection layer in patterning, a low-reflection layer formed as necessary on the uppermost layer of the absorption layer 3 for the purpose of improving the contrast during inspection of the mask pattern (a low-reflection layer in a wavelength region of inspection light for the mask pattern), a low-reflection layer formed for the purpose of controlling the reflectance at an EUV wavelength, and a phase control layer deposited for the purpose of controlling the phase at an EUV wavelength.

Examples of the combination of layers in the multi-layered configuration include Pt/Ru, Ir/Ru, Pt/Ta, Pt/Ta₂O₅, Ir/Cr, and Ir/Ta₂O₅. The constituent materials of the layer such as Pt, Ru, Ir, Ta, Ta₂O₅ and Cr may be in the form of an alloy, a nitride, an oxynitride, a boride or the like depending on required characteristics such as optical characteristics, crystallinity, etching properties and durability. The lamination order is not limited. For example, in the case of a two-layered configuration described above, the order of first layer/second layer is preferable.

The refractive index and the extinction coefficient in the case of a multi-layered configuration are determined as a weighted average value of the refractive indexes and extinction coefficients of the layers with each layer thickness taken into account.

The absorption layer 3 can be formed by, for example, depositing the constituent films to a desired thickness using a known deposition method such as a magnetron sputtering method or an ion beam sputtering method.

An absorption layer as described above enables exhibition of an effect as a phase shift mask which can transfer fine line-like patterns with high dimension accuracy while suppressing shadowing when the total thickness of the absorption layer 3 is 60 nm or less. From the viewpoint of the efficiency of deposition of the absorption layer 3 and etching during formation of the mask pattern, the total thickness of the absorption layer 3 is preferably thin, and preferably 60 nm or less, more preferably 58 nm or less, and further more preferably 45 nm or less. From the viewpoint of the EUV light absorbing effect, the total thickness of the absorption layer 3 is preferably 20 nm or more.

### (Antireflection Film)

When DUV light (deep ultraviolet light) having a wavelength of 190 to 260 nm is used in an inspection process, an antireflection film for preventing reflection (not shown) may be laminated on the absorption layer 3.

The reflective mask may undergo mask inspection to examine defects of the mask pattern formed on the absorption layer 3. In the mask inspection, whether defects are present or not, or the like is determined mainly on the basis of optical data of reflected rays of inspection light, and therefore as the inspection light, light that passes through the mask cannot be used, and DUV light is used. From the viewpoint of accurate inspection, it is preferable that an antireflection film for preventing reflection of DUV light which is inspection light be provided on the absorption layer 3.

For playing the above-described role, the antireflection film is preferably formed of a material having a lower refractive index for DUV light than the absorption layer 3. Examples of the constituent material of the antireflection film include materials containing Ta as a main component, and one or more components selected from the group consisting of Hf, Ge, Si, B, N, H and O in addition to Ta. Specific examples thereof include TaO, TaON, TaONH, TaHfO, TaHfON, TaBSiO, and TaBSiON.

The antireflection film can be formed by, for example, deposition to a desired thickness using a known deposition method such as a magnetron sputtering method or an ion beam sputtering method.

### (Other Configurations)

The reflective mask blank of the present embodiment may be provided with, in addition to the above-described films and layers, functional films known for reflective mask blanks.

For example, for absorptive fixation of the reflective mask blank 10 to, for example, a mount section of an electrostatic chuck, a back electroconductive film may be formed on a surface of the substrate 1 on a side opposite to the multi-layer reflection film 2 (back surface).

The back electroconductive film preferably has a sheet resistance of 100Ω/□ or less, and can be set to a known configuration. Examples of the constituent material of the back electroconductive film include Si, TiN, Mo, Cr, and TaSi. The thickness of the back electroconductive film can be, for example, 10 to 1,000 nm.

The back electroconductive film can be formed by, for example, deposition to a desired thickness using a known deposition method such as a magnetron sputtering method, an ion beam sputtering method, a chemical vapor deposition method (CVD method), a vacuum vapor deposition method or an electroplating method.

The reflective mask blank of the present invention has an EUV light reflectance of preferably 0.1 to 20%, more preferably 0.5 to 15%, further more preferably 1.0 to 10%, even more preferably 1.5 to 8.0%.

### [Reflective Mask]

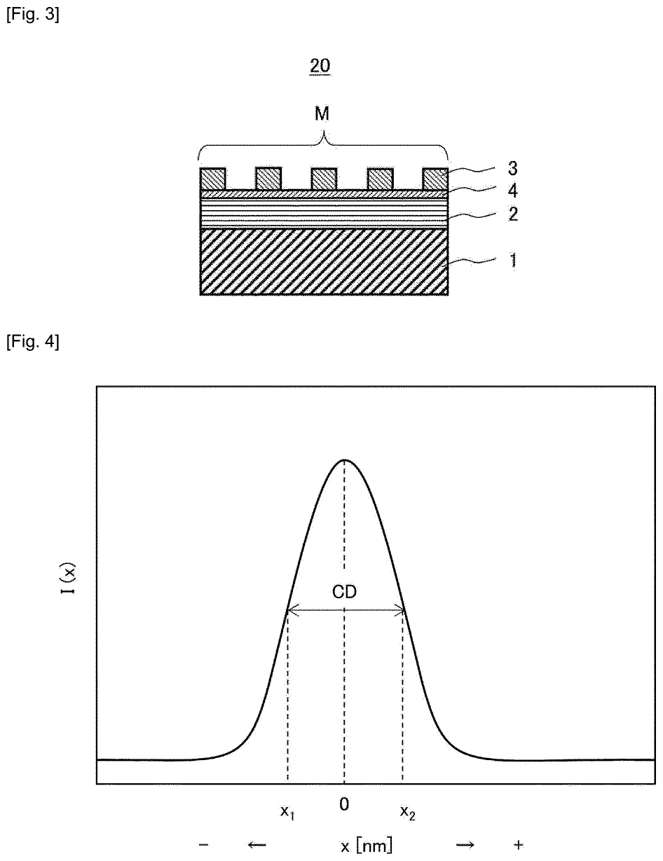

FIG. 3 schematically show a cross-section of a reflective mask of the present embodiment. A reflective mask 20 shown in FIG. 3 is a reflective mask for EUV lithography in which the multi-layer reflection film 2 that reflects EUV light and the absorption layer 3 that absorbs EUV light are laminated on the substrate 1 in the stated order from the substrate 1 side, wherein the absorption layer 3 has a refractive index of 0.95 or less and an extinction coefficient of 0.025 or more for EUV light having a wavelength of 13.5 nm, a phase difference between reflected light from a surface of the multi-layer reflection film 2 and reflected light from a surface of the absorption layer 3 is 220 to 280°, and preferably 225 to 280° with respect to an incident ray of the EUV light having a wavelength of 13.5 nm, and a mask pattern M is formed on the absorption layer 3.

That is, the reflective mask of the present invention is such that the mask pattern M is formed on the absorption layer 3 of the reflective mask blank 10 of the present embodiment. Therefore, the descriptions of the layers forming the reflective mask 20 are the same as those for the reflective mask blank 10 above, and are therefore omitted.

The mask pattern M, which meets a more complicated pattern, can be configured such that it includes a first line-like pattern and a second line-like pattern, the line directions of which orthogonally cross each other as described for the reflective mask blank 10 above. That is, the mask pattern M is preferably for performing transfer of an LS pattern including the first line-like transfer pattern L1 and the second line-like transfer pattern L2 shown in FIGS. 2A and 2B.

The reflective mask 20 is suitable when the LS pattern including the first line-like transfer pattern L1 and the second line-like transfer pattern L2 includes fine line-like patterns as described for the reflective mask blank 10 above. For example, HP is preferably 18 nm or less, and more preferably 16 nm or less.

When the HP of the line-like patterns is within the above-described range, a further excellent effect as a phase shift mask with high transfer accuracy can be obtained.

In the present invention, excellent transfer accuracy of the reflective mask 20 can be presumed by the normalized image log slope (NILS). NILS is a characteristic value representing a contrast of light intensity between a light portion and a dark portion in the transfer pattern. It can be said that the contrast of the transfer pattern increases and transfer accuracy becomes better as the value of NILS becomes higher. NILS is determined by the following expression (5).

$$NILS = CD \times \frac{\partial ln I ( x )}{\partial x} \qquad ( 5 )$$

In the expression (5), I(x) represents a light intensity distribution (intensity normalized with the maximum intensity, non-dimensional parameter) in the transfer pattern, x represents a distance (unit: nm) from the position of a peak in a line width direction of the transfer pattern, and CD represents a critical dimension of the line width at a resolution limit of the transfer pattern.

FIG. 4 shows an outline of the light intensity distribution I(x). As shown in FIG. 4, NILS is determined as a product of CD and a slope of In I(x) (natural logarithm of I(x)) when the width of I(x) in the peak portion (x₂−x₁) is equal to CD.

I(x) is determined by lithography simulation based on a known optical imaging theory (see, for example, Koichi Matsumoto, “Lithography Optics”, “Kogaku”, the Optical Society of Japan, March 2001, Vol. 30, No. 3, p. 40-47). For the simulation, commercially available software (for example, Lithography Simulator “PROLITH” manufactured by KLA-Tencor Corporation); “Sentaurus Lithography” manufactured by Synopsys, Inc.) can also be used.

In the present invention, simulation was performed on the assumption that the numerical aperture NA of the lens of the EUV exposure apparatus is 0.33, or 0.55 with consideration given to a next-generation type for finer patterns.

In the case of NA=0.33, the scale of the mask pattern is 4 times in both length and width, and the size of each of the first line-like pattern and the second line-like pattern formed on the absorption layer 3 of the reflective mask 20 is assumed to be 4 times of CD, that is, 4 times of HP of the LS pattern of the transfer pattern.

In the case of NA=0.55, the scale of the mask pattern is 8 times in length (scan direction) and 4 times in width, the size of the first line-like pattern corresponding to the first line-like transfer pattern L1 is assumed to be 8 times of CD, that is, 8 times of HP of the first line-like transfer pattern, and the size of the second line-like pattern corresponding to the second line-like transfer pattern L2 is assumed to be 4 times of CD, that is, 4 times of HP of the second line-like transfer pattern.

At each assumed set value of HP, calculation was repeatedly performed while the refractive index n was changed within the range of 0.88 to 0.96, the extinction coefficient k was changed within the range of 0.015 to 0.065, and the thickness of the absorption layer, d was changed within the range of 20 to 80 nm, and d giving maximum NILS (optimum value) was determined at predetermined n and k. From the values of d, n and k at this time, an optimum value of phase difference was determined.

The setting conditions for the EUV exposure apparatus in simulation are shown below.

### <NA=0.33>

EUV exposure light: λ=13.5 [nm], incidence angle 6°
Scale of mask pattern: 4 times in both length and width
HP (=CD)=13 to 20 [nm]
Lighting system: double pole lighting; the optimum values of coherence factors σₒᵤₜ and σᵢₙ at each HP are shown in Table 1.

### <NA=0.55>

EUV exposure light: λ=13.5 [nm], incidence angle 5.355° Scale of mask pattern: 8 times in length, 4 times in width
HP (=CD)=8 to 14 [nm]
Lighting system: double pole lighting; the optimum values of coherence factors σₒᵤₜ and σᵢₙ at each HP are shown in Table 1.

TABLE 1

| NA | HP [nm] | σₒᵤₜ | σᵢₙ |
|---|---|---|---|
| 0.33 | 20 | 0.5 | 0.3 |
| | 18 | 0.6 | 0.4 |
| | 16 | 0.7 | 0.5 |
| | 15 | 0.8 | 0.6 |
| | 14 | 0.9 | 0.7 |
| | 13 | 0.9 | 0.7 |
| 0.55 | 14 | 0.5 | 0.3 |
| | 13 | 0.6 | 0.4 |
| | 12 | 0.7 | 0.5 |
| | 10 | 0.7 | 0.5 |
| | 9 | 0.8 | 0.6 |
| | 8 | 0.9 | 0.7 |

As shown in FIGS. 2A and 2B, the line width of the first line-like transfer pattern L1 and the corresponding first line-like pattern of the mask pattern is perpendicular to the plane of incidence of exposure light I. On the other hand, the line width of the second line-like transfer pattern L2 and the corresponding second line-like pattern of the mask pattern is parallel to the plane of incidence of exposure light I.

Preferably, the reflective mask 20 satisfies all of the following expressions (1) to (3):

$${N}_{V} \geq 2.8 \qquad ( 1 )$$

$${N}_{H} \geq 2.8 \qquad ( 2 )$$

$$\vert {N}_{V} - {N}_{H} \vert / min \{ {N}_{V} , {N}_{H} \} < 0.06 \qquad ( 3 )$$

wherein N_{V} represents NILS of the first line-like transfer pattern L1, and N_{H} represents NILS of the second line-like transfer pattern L2.

N_{V} and N_{H} are preferably high, and are each preferably 2.80 or more, and more preferably 2.85 or more, from the viewpoint of a good contrast of the transfer pattern.

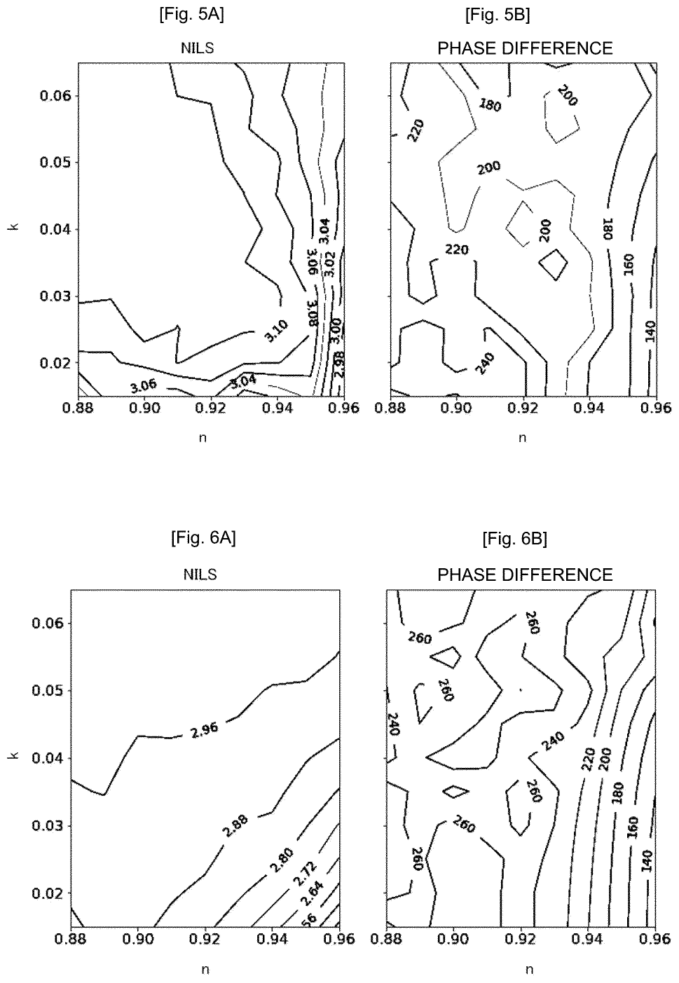

FIGS. 5A and 5B show graphs of calculation results for NA=0.33 and HP=20 [nm]. FIG. 5A is a distribution chart in which the value of N_{V} or N_{H}, whichever is lower, i.e., min {N_{V}, N_{H}}, is represented in the form of contour lines. This means that N_{V} and N_{H} are both equal to or larger than the value of NILS represented in the form of contour lines. For predetermined n and k, d at which the value of NILS reaches a maximum (optimum value) is determined. FIG. 5B shows phase differences calculated from the values of d, n and k here and represented in the form of contour lines.

For HP=20 [nm], NILS is higher at lower n and higher k according to FIG. 5A, and it can be said that the preferred phase difference here is apparently within the range of about 180 to 216° according to FIG. 5B.

FIGS. 6A and 6B shows graphs of calculation results for NA=0.55 and HP=12 [nm]. Similarly to FIG. 5A, FIG. 6B shows min {N_{V}, N_{H}} represented in the form of contour lines. FIG. 6B shows phase differences calculated from the values of d, n and k here and represented in the form of contour lines.

For HP=12 [nm], NILS is ≥2.80 or more at n≤0.930 and k≥0.025 according to FIG. 6A, and it is confirmed from FIG. 6B that the phase difference here is within the range of about 220 to 280°.

The reason why the phase difference at which the value of NILS reaches a maximum increases when the value of HP is small may be as follows.

In a reflective mask with an LS pattern, photofields continuously change at boundary portions between spaces and lines (irregularities) of the mask pattern. If the value of HP decreases, continuous cycles of irregularities of the mask pattern shorten, and accordingly, the cycle of photofields at the boundary portions of irregularities of the mask pattern shortens as compared to a case where the value of HP is large. That is, if the value of HP is substantially equal to or smaller than the wavelength of EUV exposure light (13.5 nm), distortion of the field in the mask pattern may increase, resulting in occurrence of a phenomenon in which the actual phase difference between the space and the line of the mask pattern is smaller than intended. Thus, in the case where the value of HP is small, the effect of the phase shift mask can be attained by using a mask blank prepared so as to generate a larger phase difference by, for example, adjustment of the thickness of the absorption layer 3 in advance.

If NILS varies by direction of the line-like transfer pattern, it is necessary to design with HP adjusted for each line direction of the mask pattern. Therefore, from the viewpoint of ease of designing the mask pattern, the difference in value of NILS is preferably small across all the line directions. That is, it can be said that a smaller difference between N_{V} and N_{H} enables formation of the transfer pattern with higher dimension accuracy across all the directions of the line-like pattern. From such a viewpoint, the ratio of difference which is represented by |N_{V}−N_{H}|/min {N_{V}, N_{H}} is preferably less than 0.060, more preferably 0.055 or less, and further more preferably 0.050 or less in consistency with the expression (3).

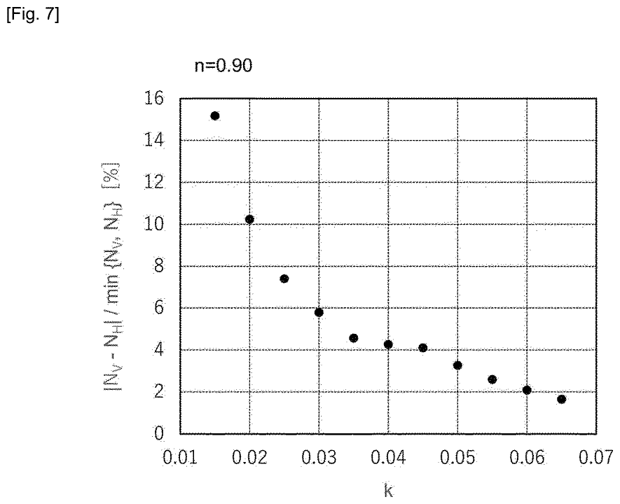

FIG. 7 shows a graph of a relationship between k and |N_{V}−N_{H}/min {N_{V}, N_{H}} which is based on calculation results in the case of NA=0.33, HP=16 [nm] and n=0.90. From FIG. 7, it can be confirmed that the value of |N_{V}−N_{H}|/min {N_{V}, N_{H}} decreases as the value of k becomes higher. From the results, it can be seen that for decreasing the value of |N_{V}−N_{H}|/min {N_{V}, N_{H}}, k is preferably 0.025 or more, more preferably 0.028 or more, and further more preferably 0.030 or more. This is because N_{V} and N_{H} are such that the value of k has little effect on N_{V}, whereas increased k leads to higher N_{H}, and decreases the difference between N_{V} and N_{H}.

In addition, the following is a reason why N_{H} becomes lower as the value of k decreases. N_{H} is NILS when the plane of incidence of exposure light I is parallel to the line width direction (see FIG. 2B), where the lateral wall of the space (recessed portion) of the mask pattern is irradiated with a part of exposure light I incident to the mask pattern. A part of reflected light from the multi-layer reflection film 2 is absorbed by the lateral wall of the recessed portion of the mask pattern. Thus, N_{H} decreases under influence of shadowing caused by irregular structures of the mask pattern, and the second line-like transfer pattern L2 tends to be inferior in dimension accuracy to the first line-like transfer pattern L1.

Therefore, when the value of k is high, light absorption at the absorption layer 3 increases, so that influences such as generation of scattered light due to shadowing can be suppressed.

Similar results can be obtained in the case of NA=0.55.

Tables 3 and 4 show optical simulation results of the phase difference θ, NILS and the total thickness d (optimum value) of the absorption layers 3 at predetermined HP of the transfer pattern (LS pattern) in EUV lithography for the absorption layers 3 of the reflective mask blank 10 of the present embodiment which are formed from various materials that are specifically shown. Table 3 shows the results for NA=0.33, and Table 4 shows the results for NA=0.55.

For the absorption layers 3 shown in Tables 3 and 4, the values of optical constants (n, k) of the metal elements are as shown in Table 2, and the compositions of the alloys are Pd_{0.79}Cr_{0.21}, Ir_{0.25}Mo_{0.75}, Os_{0.14}Ru_{0.86}, Ru_{0.5}Pt_{0.5}, Ru_{0.3} Ta_{0.7}, Ru_{0.55}Ir_{0.45}, and Os_{0.6}Re_{0.4}. The optical constants of the alloys also depend on the density and film formation conditions in a precise sense, and therefore are represented by representative values. The term “Ir/Ta₂O₅ (10 nm)” in Table 3 means that the absorption layers 3 has a two-layered structure in which from the substrate 1 side, the first layer is an Ir film and the second layer is a Ta₂O₅ film (thickness: 10 nm).

TABLE 2

| Metal | Refractive | Extinction |
|---|---|---|
| element | index n | coefficient k |
| Pd | 0.876 | 0.046 |
| Cr | 0.932 | 0.039 |
| Ir | 0.905 | 0.044 |
| Mo | 0.924 | 0.006 |
| Os | 0.904 | 0.043 |
| Ru | 0.886 | 0.017 |
| Pt | 0.891 | 0.060 |
| Ta | 0.957 | 0.034 |
| Re | 0.915 | 0.040 |

TABLE 3
NA = 0.33

| | Absorption layer | | | | | | | |
|---|---|---|---|---|---|---|---|---|
| | | | | d (optimum | Phase | NILS | | |
| HP | | | | value) | difference | | | \|N_{V} − N_{H}\|/ |
| [nm] | Material | n | k | [nm] | [°] | N_{V} | N_{H} | min{N_{V}, N_{H}} |
| 14 | PdCr | 0.920 | 0.040 | 53 | 246 | 2.89 | 2.97 | 0.027 |
| 15 | | | | 53 | 246 | 2.93 | 3.02 | 0.028 |
| 16 | | | | 47 | 225 | 2.98 | 3.03 | 0.015 |
| 18 | | | | 46 | 216 | 3.04 | 3.10 | 0.018 |
| 14 | Ir | 0.905 | 0.044 | 46 | 248 | 2.91 | 3.00 | 0.033 |
| 15 | | | | 40 | 230 | 2.95 | 3.02 | 0.021 |
| 16 | | | | 40 | 230 | 2.99 | 3.06 | 0.023 |
| 18 | | | | 39 | 216 | 3.05 | 3.10 | 0.015 |
| 14 | IrMo | 0.910 | 0.035 | 47 | 247 | 2.88 | 2.98 | 0.035 |
| 15 | | | | 48 | 251 | 2.91 | 2.94 | 0.011 |
| 16 | | | | 49 | 237 | 2.95 | 2.96 | 0.001 |
| 18 | | | | 45 | 218 | 3.12 | 2.99 | 0.043 |
| 14 | OsRu | 0.900 | 0.040 | 40 | 237 | 2.91 | 3.00 | 0.031 |
| 15 | | | | 40 | 237 | 2.94 | 3.05 | 0.039 |
| 16 | | | | 40 | 237 | 2.97 | 3.08 | 0.034 |
| 18 | | | | 39 | 223 | 3.12 | 3.03 | 0.031 |
| 14 | RuPt | 0.890 | 0.030 | 42 | 261 | 2.88 | 2.91 | 0.010 |
| 15 | | | | 42 | 261 | 2.90 | 2.97 | 0.022 |
| 16 | | | | 42 | 261 | 2.94 | 2.98 | 0.015 |
| 18 | | | | 34 | 215 | 3.12 | 3.12 | 0.000 |
| 14 | Ir/ | 0.914 | 0.041 | 54 | 255 | 2.90 | 2.91 | 0.004 |
| 15 | Ta₂O₅ | 0.915 | 0.041 | 49 | 229 | 2.95 | 2.95 | 0.001 |
| 16 | (10 nm) | 0.915 | 0.041 | 50 | 229 | 2.98 | 3.01 | 0.007 |
| 18 | | 0.916 | 0.041 | 47 | 220 | 3.05 | 3.07 | 0.009 |
| 15 | TaBN | 0.951 | 0.031 | 60 | 169 | 2.78 | 2.83 | 0.019 |
| 15 | RuTa | 0.907 | 0.022 | 49 | 251 | 2.84 | 3.01 | 0.060 |

TABLE 4
NA = 0.55

| | Absorption layer | | | | | | | |
|---|---|---|---|---|---|---|---|---|
| | | | | d (optimum | Phase | NILS | | |
| HP | | | | value) | difference | | | \|N_{V} − N_{H}\|/ |
| [nm] | Material | n | k | [nm] | [°] | N_{V} | N_{H} | min{N_{V}, N_{H}} |
| 9 | Pt | 0.891 | 0.060 | 33 | 230 | 2.94 | 2.97 | 0.011 |
| 10 | | | | 40 | 273 | 3.00 | 3.01 | 0.003 |
| 12 | | | | 46 | 273 | 2.99 | 2.99 | 0 |
| 13 | | | | 46 | 273 | 2.99 | 2.99 | 0.001 |
| 9 | Ir | 0.905 | 0.044 | 47 | 268 | 2.92 | 2.95 | 0.010 |
| 10 | | | | 47 | 268 | 3.03 | 2.97 | 0.019 |
| 12 | | | | 47 | 268 | 3.01 | 2.94 | 0.024 |
| 13 | | | | 46 | 248 | 3.08 | 2.94 | 0.047 |
| 9 | RuIr | 0.900 | 0.030 | 48 | 278 | 2.90 | 2.92 | 0.007 |
| 10 | | | | 48 | 278 | 3.02 | 2.91 | 0.040 |
| 12 | | | | 47 | 267 | 2.99 | 2.89 | 0.035 |
| 13 | | | | 46 | 252 | 2.99 | 2.95 | 0.013 |
| 9 | OsRe | 0.910 | 0.040 | 47 | 252 | 2.94 | 2.93 | 0.004 |
| 10 | | | | 47 | 252 | 3.06 | 2.93 | 0.046 |
| 12 | | | | 47 | 252 | 3.05 | 2.94 | 0.035 |
| 13 | | | | 46 | 237 | 3.10 | 2.93 | 0.058 |
| 12 | TaBN | 0.951 | 0.031 | 46 | 127 | 2.68 | 2.42 | 0.106 |
| 12 | RuTa | 0.907 | 0.022 | 48 | 253 | 3.07 | 2.83 | 0.087 |

As can be seen from Tables 3 and 4, in the case of TaBN which has a refractive index of more than 0.930, the phase difference is as small as less than 180° even though the thickness of the absorption layer is increased, and it is difficult to obtain a transfer pattern having a high contrast. In the case of RuTa which has a low extinction coefficient, the ratio of difference between N_{V} and N_{H} is large, and it is difficult to obtain a transfer pattern with high dimension accuracy.

Even when the refractive index is 0.930 or less and the extinction coefficient is 0.025 or more, setting HP of the transfer pattern to 18 nm may lead to high N_{V} and N_{H} even though the phase difference is less than 220°. On the other hand, it can be said that when HP is 16 nm or less, the phase difference is 220 to 280°, and a transfer pattern with high dimension accuracy can be obtained even though the layer thickness is 60 nm or less.

The reflective mask 20 can be produced by applying a known lithography technique to the reflective mask blank 10 to form the mask pattern M. For example, a photoresist film is formed on the absorption layer 3 of the reflective mask blank 10, and processed to a resist pattern having a desired pattern shape, the absorption layer 3 is etched by dry etching or the like, and an unnecessary photoresist including a resist pattern is then removed, whereby the reflective mask 20 can be obtained in which the mask pattern M is formed on the absorption layer 3.

### REFERENCE SIGNS LIST

1 Substrate
2 Multi-layer reflection film
3 Absorption layer
4 Protective film
10 Reflective mask blank
20 Reflective mask
I Exposure light
L1 First line-like transfer pattern
L2 Second line-like transfer pattern
T Surface to be transferred
M Mask pattern

1. A reflective mask blank for EUV lithography in which a multi-layer reflection film that reflects EUV light and an absorption layer that absorbs EUV light are laminated on a substrate in the stated order from the substrate side,
wherein the absorption layer has a refractive index of 0.930 or less and an extinction coefficient of 0.025 or more for EUV light having a wavelength of 13.5 nm, and
wherein a phase difference between reflected light from a surface of the multi-layer reflection film and reflected light from a surface of the absorption layer with respect to an incident ray of the EUV light having a wavelength of 13.5 nm is 220 to 280°.

2. The reflective mask blank according to claim 1, wherein the phase difference is 225 to 280°.

3. The reflective mask blank according to claim 1, wherein a mask pattern comprising a first line-like pattern and a second line-like pattern, line directions of which orthogonally cross each other, is formed on the absorption layer.

4. The reflective mask blank according to claim 3, wherein a half-pitch of a transfer pattern formed by the first line-like pattern and the second line-like pattern is 16 nm or less.

5. The reflective mask blank according to claim 1, wherein the absorption layer comprises one or more metal elements selected from the group consisting of iridium (Ir), rhenium (Re), osmium (Os), ruthenium (Ru), platinum (Pt), palladium (Pd), gold (Au) and silver (Ag).

6. The reflective mask blank according to claim 1, wherein the absorption layer comprises one or more metal elements selected from the group consisting of platinum (Pt), palladium (Pd), gold (Au) and silver (Ag).

7. The reflective mask blank according to claim 1, wherein the absorption layer has an extinction coefficient of 0.025 to 0.040 for EUV light having a wavelength of 13.5 nm.

8. The reflective mask blank according to claim 1, wherein the absorption layer is formed by laminating two or more films.

9. The reflective mask blank according to claim 1, wherein the absorption layer has a total thickness of 60 nm or less.

10. The reflective mask blank according to claim 1, wherein a protective film for protecting the multi-layer reflection film is formed between the multi-layer reflection film and the absorption layer.

11. A reflective mask for EUV lithography in which a multi-layer reflection film that reflects EUV light and an absorption layer that absorbs EUV light are laminated on a substrate in the stated order from the substrate side,
wherein the absorption layer has a refractive index of 0.930 or less and an extinction coefficient of 0.025 or more for EUV light having a wavelength of 13.5 nm,
wherein a phase difference between reflected light from a surface of the multi-layer reflection film and reflected light from a surface of the absorption layer with respect to an incident ray of the EUV light having a wavelength of 13.5 nm is 220 to 280°, and
wherein a mask pattern is formed on the absorption layer.

12. The reflective mask according to claim 11, wherein the phase difference is 225 to 280°.

13. The reflective mask according to claim 11, wherein the mask pattern comprises a first line-like pattern and a second line-like pattern, line directions of which orthogonally cross each other.

14. The reflective mask according to claim 13, which satisfies all of the following expressions (1) to (3):
$${N}_{V} \geq 2.8 \qquad ( 1 )$$
$${N}_{H} \geq 2.8 \qquad ( 2 )$$
$$\vert {N}_{V} - {N}_{H} \vert / min \{ {N}_{V} , {N}_{H} \} < 0.06 \qquad ( 3 )$$
wherein N_{V} represents a normalized image log slope of a line-like pattern in which a plane of incidence of exposure light is perpendicular to a line width, and N_{H} represents a normalized image log slope of a line-like pattern in which a plane of incidence of exposure light is parallel to a line width.

15. The reflective mask according to claim 13, wherein a half-pitch of a transfer pattern formed by the first line-like pattern and the second line-like pattern of the reflective mask is 16 nm or less.

16. The reflective mask according to claim 11, wherein the absorption layer comprises one or more metal elements selected from the group consisting of iridium (Ir), rhenium (Re), osmium (Os), ruthenium (Ru), platinum (Pt), palladium (Pd), gold (Au) and silver (Ag).

17. The reflective mask according to claim 11, wherein the absorption layer comprises one or more metal elements selected from the group consisting of platinum (Pt), palladium (Pd), gold (Au) and silver (Ag).

18. The reflective mask according to claim 11, wherein the absorption layer has an extinction coefficient of 0.025 to 0.040 for EUV light having a wavelength of 13.5 nm.
